(19) United States
(12) Patent Application Publication
(10) Pub. No.: US 2020/0115817 A1
(43) Pub. Date: Apr. 16, 2020

(54) PRODUCTION APPARATUS FOR GALLIUM OXIDE CRYSTAL, PRODUCTION METHOD FOR GALLIUM OXIDE CRYSTAL, AND CRUCIBLE FOR GROWING GALLIUM OXIDE CRYSTAL USED THEREFOR

(71) Applicants: SHINSHU UNIVERSITY, Nagano (JP); Fujikoshi Machinery Corp.; TOYOTA JIDOSHA KABUSHIKI KAISHA, Aichi-ken (JP)

(72) Inventors: Keigo HOSHIKAWA, Nagano (JP); Toshinori TAISHI, Nagano (JP); Takumi KOBAYASHI, Nagano (JP); Etsuko OHBA, Nagano (JP); Toshimasa HARA, Aichi-ken (JP); Motohisa KADO, Aichi-ken (JP)

(21) Appl. No.: 16/557,242

(22) Filed: Aug. 30, 2019

(30) Foreign Application Priority Data
Oct. 11, 2018 (JP) 2018-192914

(51) Int. Cl. C30B 11/00; C30B 29/16; C30B 35/00

(52) U.S. Cl. CPC C30B 11/002; C30B 29/16; C30B 11/003; C30B 35/002; C30B 35/007

(57) ABSTRACT

A production apparatus and a production method for a gallium oxide crystal, including growing a gallium oxide single crystal by VB method, HB method, or VGF method, under an air atmosphere, by using a crucible containing a Pt—Ir-based alloy having an Ir content of 20 to 30 wt %, and the production apparatus (10) includes a vertical Bridgman furnace including: a base body (12); a furnace body (14) in a cylindrical shape having heat resistance, disposed on the base body (12); a lid member (18) occluding the furnace body (14); a heater (20) disposed inside the furnace body (14); a crucible bearing (30) disposed vertically movably penetrating through the base body (12); and a crucible (34) disposed on the crucible bearing (30), heated with the heater (20), the crucible (34) being a crucible (34) containing a Pt—Ir-based alloy having an Ir content of 20 to 30 wt %.

### CROSS-REFERENCE TO RELATED APPLICATION

This application is based upon and claims the benefit of priority of the prior Japanese Patent Application No. P2018-192914, filed on Oct. 11, 2018, and the entire contents of which are incorporated herein by reference.

### TECHNICAL FIELD

The present invention relates to a production apparatus for a gallium oxide crystal, which is a wide gap semiconductor for a power device considered as one of post-silicon materials, a production method for a gallium oxide crystal, and a crucible for growing a gallium oxide crystal used therefor.

### BACKGROUND ART

In recent years, power devices have received attention as a next generation device replacing a silicon (Si) device, and have been continuously developed. The share of the wide gap semiconductors for the power device is currently occupied by silicon carbide (SiC) and in a second place by gallium nitride (GaN), and gallium oxide (Ga₂O₃) having a larger band gap than SiC and GaN is drawing concern recently.

In view of the above, for enabling mass production of gallium oxide as a wide gap semiconductor for a power device, a production apparatus or a production method for a gallium oxide single crystal (which is particularly a β-Ga₂O₃ single crystal, and the following description will be made with reference to aβ-Ga₂O₃ crystal) having high quality and large size at low cost is being developed.

Iridium (Ir) has been exclusively used as a material for a vessel (crucible), in which a raw material melt for growing a β-Ga₂O₃ crystal (i.e., melting the raw material melt and solidifying the melt to produce a single crystal) is placed. For example, PTL 1 (JP-A-2004-56098), PTL 2 (JP-A-2013-103863), and PTL 3 (JP-A-2011-153054) each describe the growth of a β-Ga₂O₃ crystal. All these literatures describe the use of a crucible formed of iridium (Ir).

However, the present inventors have clarified by various experiments and theoretical studies that iridium (Ir), i.e., the currently used crucible material, has a problem. Specifically, it has been found that Ir undergoes oxidation reaction under an oxygen partial pressure exceeding several percent in a high temperature furnace exceeding 1,800° C., and is difficult to use as a stable crucible material. It has also been found that β-Ga₂O₃ undergoes decomposition reaction losing oxygen and is difficult to exist as a stable β-Ga₂O₃ melt under an oxygen partial pressure of 10% or less at a high temperature exceeding 1,800° C.

As described above, the oxygen partial pressure condition in a high temperature furnace that is required by β-Ga₂O₃ as a raw material melt and the oxygen partial pressure condition that is required by the Ir crucible retaining the melt apparently contradict each other. Therefore, Ir is recognized as not being a crucible material that is suitable for retaining the β-Ga₂O₃ raw material melt.

In addition, the β-Ga₂O₃ crystal growth using an Ir crucible has been enabled under a narrow oxygen partial pressure range of several percent in the furnace, but it has been experimentally clarified that the grown β-Ga₂O₃ crystal has oxygen defects in a high density, which frequently occur in an oxide crystal grown under insufficient oxygen, and has problems, such as evaporation, weight reduction, and deterioration, caused by oxidation of Ir. Furthermore, there are many problems in achieving a semiconductor device, for example, the oxygen defects act like an n-type impurity to form a donor in a high concentration, which makes significantly difficult to produce a p-type β-Ga₂O₃.

Under the circumstances, the present inventors have made earnest investigations for solving the problems, and have found that an alloy of platinum (Pt) and rhodium (Rh) (which may be referred to as a Pt—Rh alloy or a Pt/Rh alloy) is suitable as a crucible material used for growing a β-Ga₂O₃ crystal (see PTL 4 (JP-A-2016-79080)). According to the production method and the production apparatus for a β-Ga₂O₃ crystal using a crucible formed of the Pt—Rh alloy, an oxygen partial pressure that is necessary and sufficient for the requirement in view of the crystal growth condition and the characteristics of the grown crystal can be applied by using a Pt—Rh-based alloy crucible suitable for the crystal growing method. Accordingly, the occurrence of oxygen defects in the crystal, which is a large issue in the ordinary crystal growing method using an iridium (Ir) crucible, can be largely reduced, and thus a β-Ga₂O₃ crystal can be favorably grown under an air atmosphere (in the atmosphere) with a high oxygen atmosphere.

### SUMMARY OF INVENTION

### Technical Problem

However, the growth of a β-Ga₂O₃ crystal under an air atmosphere (in the atmosphere) has been enabled by the invention relating to a crucible formed of a Pt—Rh-based alloy, but there arises another problem that the β-Ga₂O₃ crystal, which is originally colorless and transparent, is colored yellow or orange. The phenomenon is caused by rhodium (Rh) as one of the crucible materials that is eluted and mixed in the melt during the process of the crystal growth of β-Ga₂O₃, and the growth of a β-Ga₂O₃ crystal having high purity with less impurities is being demanded although the influence of the impurities on the semiconductor properties of the β-Ga₂O₃ crystal has not yet been reported.

### Solution to Problem

In response to the above issue, one or more aspects of the present invention are directed to a production apparatus and a production method for a gallium oxide crystal that are capable of growing a gallium oxide single crystal having high purity with less impurities without coloration, for example, in growth of a gallium oxide crystal as a wide gap semiconductor material for a future power device, and a crucible used therefor.

In view of the above, the following embodiments are described below.

The crucible for growing a gallium oxide crystal according to the present invention is a crucible for growing a gallium oxide crystal by applying a VB method, an HB method, or a VGF method, under an air atmosphere, the crucible containing a Pt—Ir-based alloy having an Ir content of 20 to 30 wt %.

The production method for a gallium oxide crystal according to the present invention is a method including growing a gallium oxide crystal by applying a VB method, an HB method, or a VGF method, under an air atmosphere, by using a crucible containing a Pt—Ir-based alloy having an Ir content of 20 to 30 wt %.

The production apparatus for a gallium oxide crystal according to the present invention is an apparatus producing a gallium oxide crystal, including a vertical Bridgman furnace including: a base body; a furnace body in a cylindrical shape having heat resistance, disposed on the base body; a lid member occluding the furnace body; a heater disposed inside the furnace body; a crucible bearing disposed vertically movably penetrating through the base body; and a crucible disposed on the crucible bearing, heated with the heater, the crucible containing a Pt—Ir-based alloy having an Ir content of 20 to 30 wt %.

The heater may be a resistance heater or a high frequency induction heater.

As described above, the present invention uses a crucible of a Pt—Ir-based alloy, which is different from an elemental substance of Ir and a Pt—Rh-based alloy, for growing a gallium oxide crystal at a high temperature of the melting point of gallium oxide or higher under an air atmosphere (in the atmosphere).

In the production method and the production apparatus for a gallium oxide crystal according to the present invention, the oxidation reaction of Ir can be prevented from occurring even under an oxygen partial pressure that is necessary and sufficient for the requirement in view of the crystal growth condition and the characteristics of the grown crystal, by using the Pt—Ir-based alloy crucible suitable for the crystal growing method, and therefore the occurrence of oxygen defects in the crystal, which is a large issue in the ordinary crystal growing method using an Ir crucible, can be largely reduced, so as to provide a single crystal having high quality.

### Advantageous Effects of Invention

According to the production method and the production apparatus for a gallium oxide crystal of the present invention, a gallium oxide (particularly 13-Ga₂O₃) crystal can be favorably growing under an air atmosphere (in the atmosphere) by using a crucible containing a Pt—Ir-based alloy having an Ir content of 20 to 30 wt %, and thus a gallium oxide crystal having a large size, high quality, and less defects can be produced. Furthermore, a colorless and transparent gallium oxide crystal without coloration can be produced (grown) by using the crucible containing a Pt—Ir-based alloy having an Ir content of 20 to 30 wt % according to the present invention, and thus a gallium oxide crystal having high purity with less impurities can be produced (grown).

### BRIEF DESCRIPTION OF DRAWINGS

FIG. 1 is a graph showing the high temperature volatilization loss of Pt group elements in the air atmosphere at a high temperature range.

FIG. 2 is a graph showing the relationship between the composition (wt %) of a Pt/Ir alloy and the melting point.

FIG. 3 is photographs showing the surface states of the alloy specimens (plate materials) of Pt/Ir (90/10 wt %), Pt/Ir (80/20 wt %), and Pt/Rh (80/20 wt %) before and after heating in the heating experiment.

FIG. 4 is a schematic illustration (elevational view) showing an example of the structure of the production apparatus for a gallium oxide crystal according to the present invention using a resistance heater.

FIG. 5 is a schematic illustration (elevational view) showing an example of the structure of the production apparatus for a gallium oxide crystal according to the present invention using a high frequency induction heater.

FIGS. 6A and 6B are photographs showing the state of the β-Ga₂O₃ raw material placed in the Pt/Ir (74/26 wt %) alloy crucible before heating (FIG. 6A) and after melting and solidification (FIG. 6B).

FIGS. 7A and 7B are photographs showing the state of the Pt/Ir (74/26 wt %) alloy crucible before heating (FIG. 7A) and after heating (FIG. 7B).

### DESCRIPTION OF EMBODIMENTS

The crucible for growing a gallium oxide crystal according to the present invention is a crucible for growing a gallium oxide crystal by applying a VB method, an HB method, or a VGF method, under an air atmosphere, the crucible containing a Pt—Ir-based alloy having an Ir content of 20 to 30 wt %.

The production method for a gallium oxide crystal according to the present invention is a method for a gallium oxide crystal, including growing a gallium oxide crystal by applying a VB method, an HB method, or a VGF method, under an air atmosphere, by using a crucible containing a Pt—Ir-based alloy having an Ir content of 20 to 30 wt %.

The present invention will be described in more detail below.

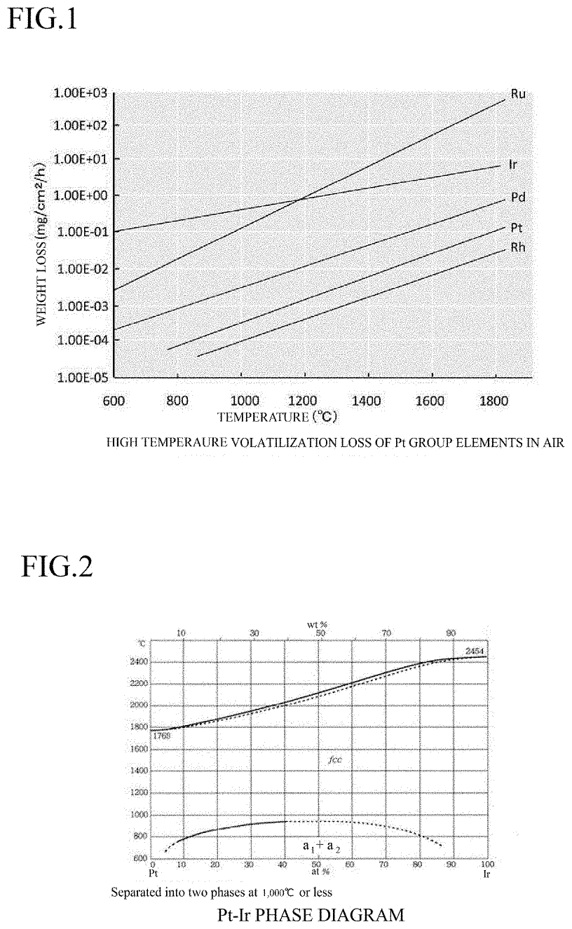

FIG. 1 is a graph showing the high temperature volatilization loss of Pt group elements, which have relatively high melting points and are considered to have a possibility of the use as a crucible material, in the air based on the known data, in view of the melting point of gallium oxide (β-Ga₂O₃) (approximately 1,800° C.).

As described above, iridium (Ir) has a relatively large high temperature volatilization loss, i.e., undergoes oxidation reaction at a high temperature, and thus the elemental substance of iridium (Ir) is not suitable as a stable crucible material.

Under the circumstances, the present inventors have investigated alloys of platinum (Pt) and iridium (Ir) as a crucible material used for the production of a β-Ga₂O₃ crystal, based on the known data and the results of the accurate melting and crystal growth experiments for β-Ga₂O₃.

As a result, it has been found that an alloy of platinum (Pt) and iridium (Ir) (which may be referred to as a Pt—Ir alloy or a Pt/Ir alloy) is suitable as a crucible material used for the production of a β-Ga₂O₃ crystal.

The Pt—Ir alloys have various melting points depending on the content of Ir contained in Pt. FIG. 2 shows the relationship between the composition (wt %) of the Pt/Ir alloy and the melting point, prepared based on the data from the know literatures and the experimental data by the present inventors.

The experiment for the measurement of the melting point of the Pt—Ir alloy was performed in the air (in the atmosphere) (having an oxygen partial pressure of approximately 20%), and the results shown in FIG. 2 were confirmed to have no significant difference from the data obtained under an argon (Ar) gas atmosphere having an oxygen partial pressure of 10 to 50% and a nitrogen (N₂) gas atmosphere having an oxygen partial pressure of 10 to 20%.

According to the melting experiment of β-Ga₂O₃ by the present inventors, β-Ga₂O₃ is completely melted at approximately 1,795° C. Accordingly, it is apparent that Pt having a melting point of 1,769° C. cannot be applied to a material of a crucible for melting and retaining β-Ga₂O₃. As shown in FIG. 2, however, a Pt/Ir alloy containing approximately 10 wt % or more of Ir has a melting point exceeding the melting point of β-Ga₂O₃, and thus can theoretically be used as a crucible for retaining a melt of β-Ga₂O₃.

(Heating Experiment of Pt—Ir-Based Alloy)

The present inventors then performed the following experiment for investigating the composition (wt %) of the Pt/Ir alloy that is optimum for the crucible material used for the production of a β-Ga₂O₃ crystal.

Alloy specimens (plate materials) of Pt/Ir (90/10 wt %) and Pt/Ir (80/20 wt %), and also Pt/Rh (80/20 wt %) as a comparative example were prepared and subjected to a heating experiment by retaining at a maximum temperature of 1,760° C. or a maximum temperature of 1,806° C. for 5 to 10 hours with a VB method crystal growth furnace under an air atmosphere, and the surface states of the alloy plate materials were observed and analyzed before and after heating. It has been demonstrated by the present inventors that the alloy of Pt/Rh (80/20 wt %) can be used as a crucible material used for the production of a β-Ga₂O₃ crystal (see PTL 4).

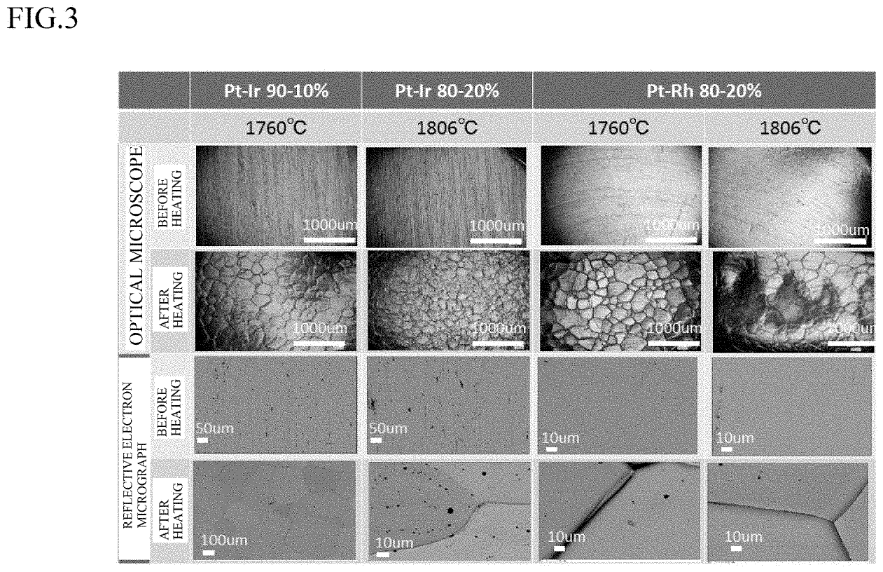

Table 1 shows the results of the change in state of the alloy plate materials used in the aforementioned experiment after heating. FIG. 3 shows micrographs of the surface states of the alloy plate materials used in the experiment.

TABLE 1

| | Pt/Ir | Pt/Ir | Pt/Rh |
|---|---|---|---|
| | (90/10 wt %) | (80/20 wt %) | (80/20 wt %) |
| 1,760° C. (60 at %) | A | A | A |
| 1,806° C. (65 at %) | B | A | A |

A: shape retained without melting
B: melted

As shown in Table 1, all the plate materials after heating to a maximum temperature of 1,760° C. retained the shape without melting. As for the plate materials after heating to a maximum temperature of 1,806° C., on the other hand, the alloy plate material of Pt/Ir (90/10 wt %) was melted due to the temperature higher than the melting point thereof, and the alloy plate materials of Pt/Ir (80/20 wt %) and Pt/Rh (80/20 wt %) retained the shape without melting.

As shown in FIG. 3, furthermore, the observation with an optical microscope of the surface states of the alloy plate materials after heating revealed that for the alloy plate material of Pt/Rh (80/20 wt %) after heating to both a maximum temperature of 1,760° C. and a maximum temperature of 1806° C., the smooth surface before heating was changed to show a grain boundary pattern, which was assumed to be caused by the progress of crystallization due to heating, but the composition bias was not confirmed. For the Pt—Ir alloy plate materials, i.e., both the alloy of Pt/Ir (90/10 wt %) heated to a maximum temperature of 1,760° C. and the alloy of Pt/Ir (80/20 wt %) heated to a maximum temperature of 1,806° C., which retained the shape thereof without melting, the smooth surface before heating was changed to show a grain boundary pattern, which was assumed to be caused by the progress of crystallization due to heating, but the composition bias was not confirmed. However, the plate material of the alloy of Pt/Ir (90/10 wt %) was melted at 1,806° C. as described above.

If a local separation (bias) of the composition occurs due to heating, the separated elements except for platinum (Pt) evaporate through the formation of oxides, with remaining platinum (Pt) being melted beyond the melting point, and consequently the alloy is melted or forms pores or cracks irrespective of the temperature lower than the melting point of the alloy. Therefore, an alloy that causes separation (bias) of the composition is not suitable as the crucible material.

As shown in FIG. 3, on the other hand, the observation with an electron microscope of the surface states of the alloy plate materials after heating revealed that for both the plate materials of the Pt—Ir alloy (Pt/Ir (80/20 wt %)) and the Pt—Rh alloy (Pt/Rh (80/20 wt %)), no separation (bias) of the composition occurred, and no pore or crack was observed in the reflective electron micrographs.

Accordingly, it is again confirmed that the Pt—Rh-based alloy (Pt/Rh (80/20 wt %)) is suitable as the crucible material, which has been clarified by the present inventors (see PTL 4). Moreover, it has been found that the Pt—Ir-based alloy (Pt/Ir (80/20 wt %)) is suitable as the crucible material.

In the practical crystal growth of β-Ga₂O₃, the melting point of the Pt/Ir alloy crucible that is required for performing the crystal growth by stably retaining the β-Ga₂O₃ melt having a melting point of 1,795° C. may vary depending on the crystal growth principles, e.g., the CZ method, the EFG method, the VB method, the HB method, and the VGF method, the size of the crystal to be grown, the crystal growth conditions, and the like.

In the case of the crystal growth of β-Ga₂O₃ by the VB method (vertical Bridgman method), the crucible necessarily withstands up to a maximum temperature of approximately 1,850° C., and therefore Pt/Ir (90/10 wt %) melted at a maximum temperature of 1,806° C. is not suitable as the crucible material for the crystal growth of β-Ga₂O₃ by the VB method (vertical Bridgman method). The lower limit of the Ir content in the Pt—Ir alloy capable of being applied to the material of the crucible for the crystal growth of β-Ga₂O₃ by the VB method (vertical Bridgman method) is effectively 20 wt % or more. On the other hand, there is a technical upper limit of the Ir content in the production of the Pt—Ir alloy, and thus the upper limit of the Ir content in the Pt—Ir alloy crucible is suitably 30 wt % or less. Accordingly, it has been found in the present invention that a Pt—Ir-based alloy crucible having an Ir content of 20 to 30 wt % is effective as the crucible used for growing a gallium oxide (β-Ga₂O₃) crystal.

(Example of Structure of Production Apparatus for Gallium Oxide Crystal)

The production apparatus for a gallium oxide (β-Ga₂O₃) crystal according to the present invention will be described. The production apparatus 10 for a gallium oxide (β-Ga₂O₃) crystal according to one embodiment of the present invention uses a crucible material that is different from an elemental substance of iridium (Ir) and an alloy of platinum (Pt) and rhodium (Rh), which is specifically an alloy material of platinum (Pt) and iridium (Ir), as the crucible material used for growing a β-Ga₂O₃ crystal.

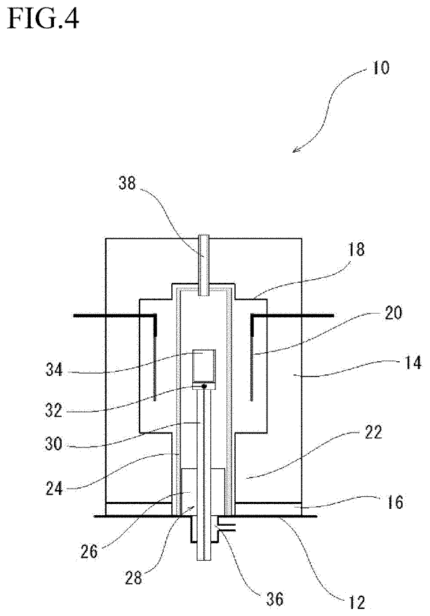

FIG. 4 is a schematic illustration (elevational view) showing an example of the structure of the production apparatus 10 for a gallium oxide crystal for growing a β-Ga₂O₃ crystal. The production apparatus 10 for a gallium oxide crystal is an apparatus that grows a β-Ga₂O₃ crystal by the VB method (vertical Bridgman method) under an air atmosphere (in the atmosphere).

In the VB method, a crucible is moved up and down, i.e., vertically moved, in a vertical Bridgman furnace having a temperature gradient in the vertical direction, and thereby a crystal is grown from the raw material in the crucible.

In the production apparatus 10 for a gallium oxide crystal, the vertical Bridgman furnace is constituted by providing a base body 12, a furnace body 14, a lid member 18, a heater 20, a crucible bearing 30, and a crucible 34, which are described below.

In FIG. 4, the furnace body 14 constituted by a heat insulating material is disposed on the base body (pedestal) 12. The base body 12 is equipped with a cooling mechanism 16, through which cooling water flows.

The furnace body 14 is in a cylindrical shape in general, and is formed to have a structure having heat resistance capable of withstanding a high temperature of approximately 1,850° C.

The upper portion of the furnace body 14 can be occluded with the lid member 18. The lower portion of the furnace body 14 constitutes a bottom portion 22 having various heat resistant materials laminated.

A furnace core tube 24 in a cylindrical shape is disposed in the furnace body 14, and the heater 20 is disposed between the furnace core tube 24 and the furnace body 14, which also is in a cylindrical shape. The heater 20 in the present embodiment is a resistance heater, which generates heat under application of electricity. At this time, a temperature gradient is formed, in which the upper side of the cylindrical furnace core tube 24 becomes a higher temperature. Examples of the material used for the heater 20 include molybdenum disilicide (MoSi₂).

A heat insulating material 26 is disposed in the bottom portion of the furnace core tube 24. The furnace core tube 24 has in the center portion thereof a through hole 28 penetrating vertically through the base body 12 and the heat insulating material 26, and through the through hole 28, the crucible bearing 30 is provided vertically movably and rotatably with the axis line as the center with a driving mechanism, which is not shown in the figure. The crucible bearing 30 is also formed of a heat resistant material withstanding a high temperature, such as alumina. A thermocouple 32 is disposed inside the crucible bearing 30 to measure the temperature in the furnace body 14.

The crucible bearing 30 can carry the crucible 34 on the upper end thereof, and the aforementioned crucible of a Pt—Ir alloy is carried thereon. The crucible 34 is heated with the heater 20.

With the aforementioned structure, the crucible 34 on the crucible bearing 30 can be heated (temperature raise) by moving the crucible bearing 30 upward in the furnace core tube 24 having a temperature gradient, in which the temperature is increased upward, and the crucible 34 on the crucible bearing 30 can be cooled (temperature fall) by moving the crucible bearing 30 downward therein. According to the procedure, the gallium oxide raw material placed in the crucible 34 can be melted and solidified to grow a gallium oxide crystal.

An air inlet tube 36 is disposed around the crucible bearing 30 under the base body 12, with which the air (oxygen) can be supplied to the furnace core tube 24 through the gap between the crucible bearing 30 and the heat insulating material 26. An exhaust tube 38 is disposed at the upper part of the furnace cure tube 24, penetrating through the furnace body 14, reaching the outside of the production apparatus 10, with which the gas inside the furnace core tube 24 can be exhausted outside the production apparatus 10. According to the configuration, the crystal growth under an air atmosphere (in the atmosphere) can be performed.

While this embodiment is configured to have a heating system of resistance heating by using a resistance heater as the heater 20, a heating system of high frequency induction heating may be employed as a modified example.

FIG. 5 is a schematic illustration (elevational view) showing an example of the structure of the production apparatus 10 for a gallium oxide crystal using a heater 42 by high frequency induction heating. The same members as the members shown in FIG. 4 are shown by the same symbols. The furnace body 14 shown in FIG. 5 is actually the same as shown in FIG. 4 although the appearance thereof in the figure is slightly different from in FIG. 4. The introduction of the external air and the exhaust from the interior of the furnace core tube 24 can be performed.

What are different in the modification example from the aforementioned embodiment include a high frequency coil 40 disposed on the outer periphery of the furnace body 14, and the heater 42 heating by high frequency induction heating disposed instead of the resistance heater 20 used in the aforementioned embodiment. Examples of the material used for the heater 42 include a Pt-based alloy material withstanding a high temperature, such as a Pt—Rh-based alloy material having a Rh content of approximately 30 wt %.

(Melting Experiment of β-Ga₂O₃ Raw Material by Production Apparatus for Gallium Oxide Crystal Using Pt—Ir Based Alloy Crucible)

The present inventors investigated as to whether the crystal growth of gallium oxide was possible by heating a β-Ga₂O₃ raw material with the aforementioned production apparatus 10 for a gallium oxide crystal using a Pt—Ir-based alloy crucible. In addition, a β-Ga₂O₃ raw material was heated by using a Pt—Rh-based alloy crucible instead of the Pt—Ir-based alloy crucible, and the β-Ga₂O₃ crystals grown by the crucibles were compared for contaminants (impurities).

The present inventors have made known that the growth of a β-Ga₂O₃ crystal is possible by using the aforementioned production apparatus 10 for a gallium oxide crystal that uses a Pt—Rh-based alloy crucible as an apparatus for growing a β-Ga₂O₃ crystal by the VB method under an air atmosphere (in the atmosphere) (see PTL 4).

Specifically, crucibles formed of Pt-based alloy materials of Pt/Ir (74/26 wt %), Pt/Rh (80/20 wt %), and Pt/Rh (70/30 wt %) were prepared, and under an air atmosphere (in the atmosphere), the Pt-based alloy crucibles having a β-Ga₂O₃ raw material (β-Ga₂O₃) placed therein each were mounted on the aforementioned production apparatus 10, and the crucible was moved upward to melt the β-Ga₂O₃ raw material by heating. Subsequently, the crucible was moved downward to solidify the molten β-Ga₂O₃ raw material by cooling (temperature fall).

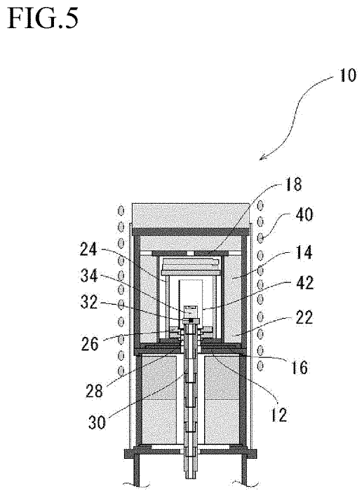

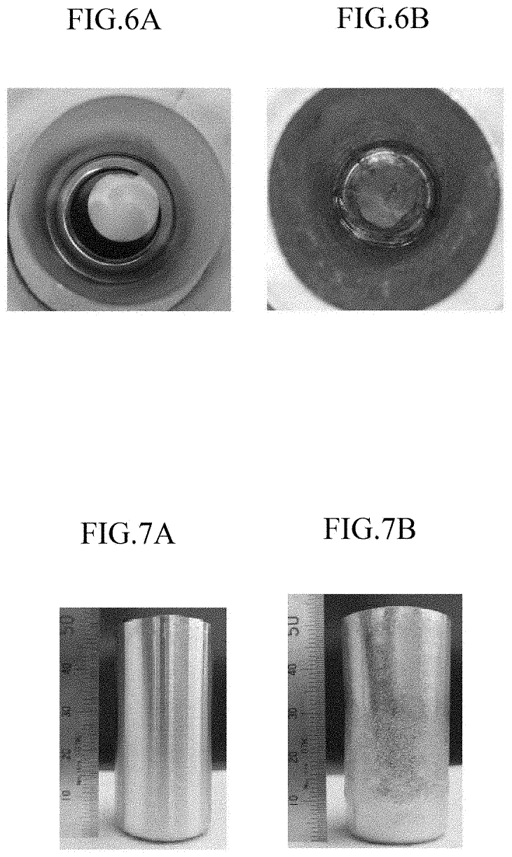

FIGS. 6A and 6B are photographs showing the state of the β-Ga₂O₃ raw material (β-Ga₂O₃) placed in the Pt/Ir (74/26 wt %) alloy crucible before heating (FIG. 6A) and after melting and solidification (FIG. 6B). FIGS. 7A and 7B are photographs showing the state of the Pt/Ir (74/26 wt %) alloy crucible before heating (FIG. 7A) and after heating (FIG. 7B).

In this experiment, the Pt/Ir (74/26 wt %) alloy crucible was heated by using the production apparatus 10 for a gallium oxide crystal with the high frequency induction heating system. The heating electric power was increased to the prescribed electric power, and then the electric power was retained for 1 hour and 51 minutes and then gradually decreased. During the experiment, since the crystal is not visible, the melting of the β-Ga₂O₃ raw material is estimated by precisely comprehending the temperature change of the crucible from the output signal of the thermocouple 32.

As shown in FIG. 6B, the massive β-Ga₂O₃ raw material (β-Ga₂O₃) before heating shown in FIG. 6A formed a colorless transparent β-Ga₂O₃ crystal after heating and cooling. This shows that the β-Ga₂O₃ raw material was totally melted in the Pt/Ir (74/26 wt %) alloy crucible to fill the whole of the crucible, and then solidified.

The temperature profile measured with the thermocouple 32 showed a constant raising rate with the increase of the heating electric power, but when the β-Ga₂O₃ raw material started to melt, the temperature raising rate once slowed down to make the temperature raise stalled, and when the β-Ga₂O₃ raw material was completely melted, the temperature raising rate returned to the original rate.

It was considered therefrom that as a result of the analysis of the actually measured temperature profile, the β-Ga₂O₃ raw material reached the melting point (1,795° C.) to start to melt when the temperature of the crucible (bottom portion) reached around 1,707.0° C. It was also considered that the β-Ga₂O₃ raw material was completely melted around 1,712.0° C.

However, in consideration of the deterioration of the thermocouple 32 used in the experiment, it was considered that the temperature of the crucible (bottom portion) was further increased over the aforementioned measured value.

As shown in FIG. 7B, the Pt/Ir (74/26 wt %) alloy crucible before heating shown in FIG. 7A suffered irregular deformation on the surface of the body thereof after heating, but retained the original shape without melting.

From the aforementioned results, the production apparatus 10 for a gallium oxide crystal using the Pt—Ir-based alloy crucible (i.e., the crucible of a (Pt/Ir (74/26 wt %) alloy) according to the embodiment of the present invention was able to perform the growth of a gallium oxide crystal (β-Ga₂O₃) by the VB method under an air atmosphere (in the atmosphere) according to the ordinary procedure. By using the crucible of a Pt—Ir-based alloy material as the crucible 34, as different from the case of an elemental substance of Ir, the crucible was able to be prevented from being oxidized irrespective of an oxygen partial pressure exceeding several percent, and due to the crystal growth in the air, which was rich in oxygen, a gallium oxide crystal (β-Ga₂O₃) without oxygen defects was able to be grown.

A gallium oxide crystal (β-Ga₂O₃) can be reliably grown by selecting the crucible material and controlling the temperature for the crystal growth, based on the melting temperature of β-Ga₂O₃ obtained from the melting experiment.

As described above, the β-Ga₂O₃ crystal formed with the Pt—Ir-based alloy crucible shown in FIG. 6B was a colorless transparent crystal inherent to a β-Ga₂O₃ crystal. On the other hand, the β-Ga₂O₃ crystals formed with the crucibles of the Pt—Rh-based alloys, i.e., Pt/Rh (80/20 wt %) and Pt/Rh (70/30 wt %), were colored yellow or orange (not shown in the figure).

The analysis results (content (ppm)) of the contaminants (impurities) of the β-Ga₂O₃ crystals grown with the crucibles of Pt/Ir (74/26 wt %), Pt/Rh (80/20 wt %), and Pt/Rh (70/30 wt %) alloys are shown in Table 2.

TABLE 2

| | Mg | Al | Si | Ca | Fe | Zr | Rh | Ir | Pt |
|---|---|---|---|---|---|---|---|---|---|
| Pt/Ir (74/ | — | 5.4 | 4.2 | — | 6.2 | — | 0.01 | 4.5 | 1.7 |
| 26 wt %) | | | | | | | | | |
| Pt/Rh (70/ | — | 1.2 | 8.5 | — | 4.3 | — | 55 | — | 0.04 |
| 30 wt %) | | | | | | | | | |
| Pt/Rh (80/ | 0.32 | 0.65 | 14 | 0.99 | 9.9 | 0.02 | 24 | 0.02 | 0.04 |
| 20 wt %) | | | | | | | | | |

As shown in Table 2, the β-Ga₂O₃ crystal formed with the Pt/Rh (80/20 wt %) alloy crucible was confirmed to have contamination of rhodium (Rh) derived from the crucible material of 24 ppm, and the β-Ga₂O₃ crystal formed with the Pt/Rh (70/30 wt %) alloy crucible was confirmed to have contamination thereof of 55 ppm. As described above, these crystals were confirmed to be colored yellow or orange due to the elution and contamination of rhodium (Rh) as the crucible material.

On the other hand, the β-Ga₂O₃ crystal formed with the Pt/Ir (74/26 wt %) alloy crucible was confirmed to have contamination of iridium (Ir) derived from the crucible material of 4.5 ppm, but had less impurities derived from the crucible material as compared to the Pt—Rh-based alloys. As described above, furthermore, a colorless transparent crystal inherent to a β-Ga₂O₃ crystal without coloration was formed (FIG. 6B).

In consideration of the production process of the β-Ga₂O₃ raw material (β-Ga₂O₃) used in the experiment, no possibility may be considered that rhodium (Rh) and iridium (Ir) are originally contained as impurities in β-Ga₂O₃.

It has been found from the aforementioned results that by using a Pt—Ir-based alloy material as a crucible for growing a gallium oxide crystal, a gallium oxide crystal (β-Ga₂O₃) having high purity with less impurities without coloration can be grown, as compared to a Pt—Rh-based alloy material.

The present invention is not limited to the aforementioned embodiments, and various modifications may be made therein unless the modifications deviate from the scope of the present invention. In particular, while the embodiment with the VB method (vertical Bridgman method) has been described for example, the present invention may be applied to the HB method (horizontal Bridgman method), the VGF method (vertical gradient freeze method), and the like.

What is claimed is:

1. A crucible for growing a gallium oxide crystal by applying a VB method, an HB method, or a VGF method, under an air atmosphere, the crucible comprising a Pt—Ir-based alloy having an Ir content of 20 to 30 wt %.

2. A production method for a gallium oxide crystal, the method comprising growing a gallium oxide crystal by applying a VB method, an HB method, or a VGF method, under an air atmosphere, by using a crucible containing a Pt—Ir-based alloy having an Ir content of 20 to 30 wt %.

3. A production apparatus for a gallium oxide crystal, the apparatus comprising a vertical Bridgman furnace including:
a base body;
a furnace body in a cylindrical shape having heat resistance, disposed on the base body;
a lid member occluding the furnace body;
a heater disposed inside the furnace body;
a crucible bearing disposed vertically movably penetrating through the base body; and
a crucible disposed on the crucible bearing, heated with the heater, the crucible containing a Pt—Ir-based alloy having an Ir content of 20 to 30 wt %.

4. The production apparatus for a gallium oxide crystal according to claim 3, wherein the heater is a resistance heater.

5. The production apparatus for a gallium oxide crystal according to claim 3, wherein the heater is a high frequency induction heater.
